(19) United States
(12) Patent Application Publication
(10) Pub. No.: US 2025/0272194 A1
(43) Pub. Date: Aug. 28, 2025

(54) DECODER SCHEME OF FLASH MEMORY CONTROLLER CAPABLE OF REDUCING READING AND WRITING FREQUENCY OF MEMORY THAT OUTPUT CODEWORD

(71) Applicant: Silicon Motion, Inc., Hsinchu County (TW)

(72) Inventors: Mao-Ruei Li, Hsinchu City (TW); Zhen-U Liu, Hsinchu County (TW)

(73) Assignee: Silicon Motion, Inc., Hsinchu County (TW)

(21) Appl. No.: 18/896,875

(22) Filed: Sep. 25, 2024

(30) Foreign Application Priority Data
Feb. 23, 2024 (TW) 113106519

(51) Int. Cl. G06F 11/10

(52) U.S. Cl. CPC G06F 11/1068; G06F 11/1004

(57) ABSTRACT

A decoding method includes: generating or updating a variable-to-check message and generating a log-likely ratio according to a channel value; generating a converted variable-to-check message according to the variable-to-check message; generating a check-to-variable message according to the converted variable-to-check message; generating a converted check-to-variable message according to the check-to-variable message to update the variable-to-check message and the log-likely ratio; performing a hard decision according to the log-likely ratio to determine whether to flip bit(s) of a specific codeword to generate an output codeword; and comparing a reference value with a hard decision result to generate a difference value and selectively writing the hard decision result into the memory circuit according to the difference value to decrease the number of performing writing operation of the memory circuit.

### BACKGROUND OF THE INVENTION

### 1. Field of the Invention

The present invention relates to a decoding scheme, and more particularly to a decoder circuit, a decoding method, and a flash memory controller.

### 2. Description of the Prior Art

Generally speaking, traditional existing technologies are limited by the impact of process yield, and the memory suppliers will limit the depth and bandwidth of the memories. Thus, the actual memory bandwidth often cannot meet the system-level requirements, and all small physical memories will operate at the same time when each time it is necessary to read and write data based on the system-level requirements. However, in a high-noise environment, such as the iterative decoding calculation of a decoder, it quite consumes power to simultaneously read and write all small physical memories each time.

### SUMMARY OF THE INVENTION

Therefore one of the objectives of the invention is to provide a decoder circuit, a decoding method, and a flash memory controller, to solve the problems.

According to the embodiments of the invention, a decoder circuit is disclosed. The decoder circuit comprises a variable node circuit, a variable-to-check circuit, a check node circuit, a check-to-variable circuit, a syndrome calculation circuit, and a memory circuit. The variable node circuit is used for receiving data of a specific codeword of an input data as a channel value to generate or update a variable-to-check message and generate a log-likely ratio to a syndrome calculation circuit. The variable-to-check circuit, coupled to the variable node circuit, is used for converting the variable-to-check message from a variable node domain into a check node domain to generate a converted variable-to-check message. The check node circuit, coupled to the variable-to-check circuit, is used for performing a minimization calculation based on the converted variable-to-check message to generate a check-to-variable message. The check-to-variable circuit, coupled to the check node circuit, is used for converting the check-to-variable message from the check node domain into the variable node domain to generate a converted check-to-variable message, to make the variable node circuit perform a sum calculation to update the variable-to-check message and perform another sum calculation to update the log-likely ratio based on the converted check-to-variable message. The syndrome calculation circuit, coupled to the variable node circuit, is used for performing a hard decision operation based on the log-likely ratio to determine whether to flip information of at least one bit in the specific codeword to generate an output codeword. The memory circuit, coupled to the syndrome calculation circuit, is used for storing the output codeword generated by the syndrome calculation circuit as an output data. The syndrome calculation circuit compares a reference value with a value of the hard decision result to generate a difference value and selectively stores and writes the hard decision result value into the memory circuit according to the difference value to reduce the number of reading and writing of the memory circuit.

According to the embodiments, a flash memory controller is disclosed. The flash memory controller comprises an encoder and a decoder circuit. The encoder is used for performing an encoding operation upon a write data sent from a host device to write the write data into a flash memory. The decoder circuit is used for performing a decoding operation upon a read data read from the flash memory to generate a decoded data. The decoder circuit comprises a variable node circuit, a variable-to-check circuit, a check node circuit, a check-to-variable circuit, a syndrome calculation circuit, and a memory circuit. The variable node circuit is used for receiving data of a specific codeword of an input data as a channel value to generate or update a variable-to-check message and generate a log-likely ratio to a syndrome calculation circuit. The variable-to-check circuit, coupled to the variable node circuit, is used for converting the variable-to-check message from a variable node domain into a check node domain to generate a converted variable-to-check message. The check node circuit, coupled to the variable-to-check circuit, is used for performing a minimization calculation based on the converted variable-to-check message to generate a check-to-variable message. The check-to-variable circuit, coupled to the check node circuit, is used for converting the check-to-variable message from the check node domain into the variable node domain to generate a converted check-to-variable message, to make the variable node circuit perform a sum calculation to update the variable-to-check message and perform another sum calculation to update the log-likely ratio based on the converted check-to-variable message. The syndrome calculation circuit, coupled to the variable node circuit, is used for performing a hard decision operation based on the log-likely ratio to determine whether to flip information of at least one bit in the specific codeword to generate an output codeword. The memory circuit, coupled to the syndrome calculation circuit, is used for storing the output codeword generated by the syndrome calculation circuit as an output data. The syndrome calculation circuit compares a reference value with a value of the hard decision result to generate a difference value and selectively stores and writes the hard decision result value into the memory circuit according to the difference value to reduce the number of reading and writing of the memory circuit.

According to the embodiments, a decoding method of a decoder circuit is disclosed. The decoding method comprises: using a variable node circuit to receive data of a specific codeword of an input data as a channel value to generate or update a variable-to-check message and generate a log-likely ratio to a syndrome calculation circuit; converting the variable-to-check message from a variable node domain into a check node domain to generate a converted variable-to-check message; using a check node circuit to perform a minimization calculation based on the converted variable-to-check message to generate a check-to-variable message; converting the check-to-variable message from the check node domain into the variable node domain to generate a converted check-to-variable message, to make the variable node circuit perform a sum calculation to update the variable-to-check message and perform another sum calculation to update the log-likely ratio based on the converted check-to-variable message; using the syndrome calculation circuit to perform a hard decision operation based on the log-likely ratio to determine whether to flip information of at least one bit in the specific codeword to generate an output codeword; providing a memory circuit for storing the output codeword generated by the syndrome calculation circuit as an output data; and, using the syndrome calculation circuit to compare a reference value with a value of the hard decision result to generate a difference value and to selectively store and write the hard decision result value into the memory circuit according to the difference value to reduce the number of reading and writing of the memory circuit.

These and other objectives of the invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a block diagram of a flash memory controller according to an embodiment of the invention.

FIG. 2 is a schematic diagram of the circuits and operations of the syndrome calculation circuit and the memory circuit shown in FIG. 1 according to the embodiment of the invention.

FIG. 3 is a schematic diagram of the circuits and operations of the syndrome calculation circuit and the memory circuit shown in FIG. 1 according to another embodiment of the invention.

FIG. 4 is a schematic diagram of a communication system circuit according to an embodiment of the invention.

### DETAILED DESCRIPTION

The present invention aims to provide a decoder circuit that can reduce the reading and writing frequency of a memory that outputs a codeword corresponding to a hard decision result during iterative decoding, to further reduce power consumption of the reading and writing can be further reduced.

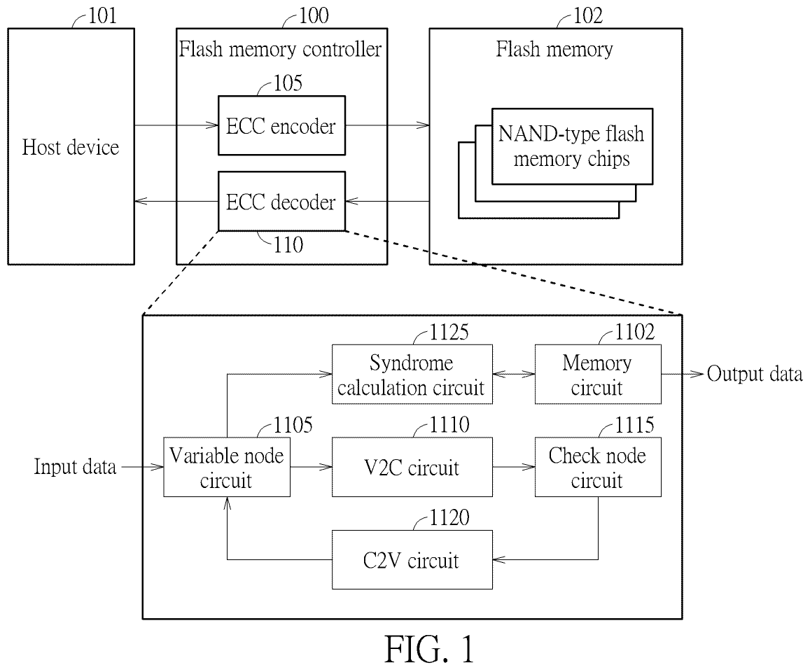

Refer to FIG. 1. FIG. 1 is a block diagram of a flash memory controller 100 according to an embodiment of the invention. As shown in FIG. 1, the flash memory controller 100 is coupled between a host device 101 and a flash memory 102. The flash memory controller 100 includes an encoder 105 and a decoder circuit 110. The encoder 105 is for example as an error correction code (ECC) encoder. The decoder circuit 110 is for example an ECC decoder. The flash memory 102 includes multiple flash memory chips such as NAND-type flash memory chips. For example, when the host device 101 writes data to one or more flash memory chips in the flash memory 102, the data to be written (for example simply called a write data) will first be sent to the flash memory controller 100. The ECC encoder 105 performs an encoding processing operation (for example, Low-density parity-check code (LDPC) encoding processing, but not limited to) upon the write data to generate an encoded write data, so as to write the encoded write data into one or more flash memory chips of the flash memory 102. In addition, when the host device 101 reads data from one or more flash memory chips in the flash memory 102, the data to be read (for example simply called a read data) will first be sent to the flash memory controller 100. The ECC decoder 110 performs a decoding processing operation (such as LDPC decoding processing, but not limited) upon the read data to generate a decoded read data, so as to transmit the decoded read data into the host device 101. It should be noted that the process of data reading/writing operations may also involve with other data processing operations such as randomization operations and de-randomization operations, etc. The modifications are suitable for the embodiments of the invention.

As shown in FIG. 1, the ECC decoder circuit 110 is, for example, an LDPC decoder circuit and includes a memory circuit 1102, a variable node circuit 1105, a variable-to-check (V2C) circuit 1110, a check node circuit 1115, a check-to-variable (C2V) circuit 1120, and a syndrome calculation circuit 1125. Specifically, the value of an input data initially received by the ECC decoder circuit 100 can be regarded as a channel value and can be stored in a channel value memory (not shown in FIG. 1) of ECC decoder circuit 100. In one embodiment, the ECC decoder circuit 100 for example is applied to a storage device, and the value of the received input data is for example the data read from one or more flash memories of the storage device. In another embodiment, the ECC decoder circuit 100 is applied to a communication system, and the value of the received input data is for example the data received from a mobile communication device such as a mobile phone. In addition, the above-mentioned channel value memory can receive and store the value of the input data in the form of a codeword, and the variable node circuit 1105 reads the input data (i.e. the stored codeword) from the channel value memory 1101. In the following paragraphs, the term ‘channel value’ is used to represent a value received by the ECC decoder circuit 100 and stored in the channel value memory 1101.

In the embodiment of the invention, one or more codewords are stored in the channel value memory. The channel value memory outputs a fragment of bits of a codeword for each time, e.g. at every processing time cycle. Each iterative decoding calculation of the LDPC decoding operation is used to sequentially process and perform calculations upon multiple fragment of bits (for example, 10 fragments) of a codeword. The number of the multiple fragments of bits in the default setting corresponds to and is equal to the number of variable nodes which is to be processed and calculated in each iterative decoding calculation, e.g. ten variable nodes. In other words, it is required to use ten processing time units to perform relevant decoding calculations for a codeword having ten fragments of bits.

The following briefly describes the concept of an iterative decoding of an LDPC decoding operation. In an iterative decoding (for example, the n-th iterative decoding, and n is a positive integer), when a specific codeword of input data (i.e. a channel value) is received and buffered from the channel value memory, the variable node circuit 1105 generates (or updates) and outputs a variable-to-check message, which is a probability value and also called as Q value, according to the specific codeword into the V2C circuit 1110, and generates (or updates) and outputs a log-likely ratio (i.e. a posterior probability value) into the syndrome calculation circuit 1125. Then, the V2C circuit 1110 performs a format conversion of variable node to check node so as to convert the variable-to-check message (Q value) from a variable node domain to a check node domain to generate a converted variable-to-check message into the check node circuit 1115. The check node circuit 1115 performs a minimization calculation based on one or more converted variable-to-check messages to generate a check-to-variable message (also called an R value which is another probability value) to the C2V circuit 1120. The C2V circuit 1120 is used to perform a format conversion of check node to variable node so as to convert the check-to-variable message (R value) from a check node domain to a variable node domain to generate a converted check-to-variable message into the variable node circuit 1105. The variable node circuit 1105 can perform a sum calculation based on one or more check-to-variable messages (R values, i.e. probability values) transmitted from the C2V circuit 1120 to generate and update the variable-to-check message (Q value), and can perform another sum calculation based on one or more check-to-variable messages (R values, i.e. probability values) transmitted from the C2V circuit 1120 to generate and update the log-likely ratio. The log-likely ratio serves as the value of the posterior probability and is outputted to the syndrome calculation circuit 1125. The generated and updated posterior probability value can be a positive value or a negative value. The syndrome calculation circuit 1125 uses the positive/negative sign of the generated and updated posterior probability value to make a hard decision to determine whether to flip information (‘0’ or ‘1’) of one or more bits in the specific codeword. The syndrome calculation circuit 1125 then calculates a syndrome value based on the result of flipped or not yet flipped information of the codeword (that is, an output data (codeword) may have bits flipped or bits not flipped). In this situation, if the calculated syndrome value is zero, then this indicates that a valid codeword is found, and the iterative decoding calculation can be interrupted and the decoding operation is completed.

The memory circuit 1102 is controlled by the syndrome calculation circuit 1125 to perform reading and writing operations to perform a hard decision operation and calculation of a syndrome value. For example, it can be used to store the output codeword generated by the syndrome calculation circuit 1125 as an output data. The syndrome calculation circuit 1125 can compare a reference value with a hard decision result of the syndrome calculation circuit 1125 to generate a difference value and selectively store and write the value of the hard decision result into the memory circuit 1102 according to the difference value, to reduce the number/frequency of reading and writing of the memory circuit 1102.

For example, in one embodiment, the memory circuit 1102 uses a first physical sub-memory to store the result of a hard decision bit and uses a second physical sub-memory to store the difference value between pre-decoded data and post-decoded data of LDPC decoding. The result of hard decision bit is the resultant output data which is outputted and has been decoded by the decoder circuit 110. The first physical sub-memory can be directly used as an output buffer, and the memory size of the first physical sub-memory is greater than or equal to the memory size of the second physical sub-memory.

For the read and write operations of the second physical sub-memory of the memory circuit 1102 controlled by the syndrome calculation circuit 1125, the syndrome calculation circuit 1125 compares the pre-decoded data and post-decoded data of LDPC decoding, e.g. comparing a reference value with a hard decision result of a (t)-th iterative decoding (i.e. the iterative decoding performed for the t-th time). When a data change occurs between the pre-decoded data and post-decoded data, the syndrome calculation circuit 1125 correspondingly generates a difference value and writes the difference value into the second physical sub-memory of the memory circuit 1102. On the contrary, if no data change occurs, then the syndrome calculation circuit 1125 does not generate the difference value and does not perform the write operation upon the second physical sub-memory of the memory circuit 1102. If no data is written into the second physical sub-memory after this current LDPC iterative decoding is finished, the syndrome calculation circuit 1125 marks an unwritten mark accordingly to record that there is no access to the second physical sub-memory of the memory circuit 1102 after the current iterative decoding is finished. Therefore, when it is required to obtain the above-mentioned difference value, the syndrome calculation circuit 1125 at first determines whether a corresponding specific address is marked with a corresponding unwritten mark. If there are no unwritten marks, the syndrome calculation circuit 1125 reads a corresponding difference value from the second physical sub-memory of the memory circuit 1102. On the contrary, if there is an unwritten mark, the syndrome calculation circuit 1125 does not perform a read operation upon the second physical sub-memory of the memory circuit 1102 and is arranged to directly use a default value as the post-decoded codeword data after the LDPC iterative decoding is finished. Therefore, this can reduce the number/frequency of reading and writing for the second physical sub-memory of the memory circuit 1102, to reduce the power consumption of reading and writing for the memory circuit 1102.

In addition, for the reading and writing of the first physical sub-memory of the memory circuit 1102 controlled by the syndrome calculation circuit 1125, the syndrome calculation circuit 1125 can compare a previous post-decoded codeword data with a next post-decoded codeword data (e.g. the hard decision result of the (t−1)-th iterative decoding and the hard decision result of the (t)-th iterative decoding) to generate a difference value to determine whether to update the information of the result of the current hard decision bit stored in the first physical sub-memory of the memory circuit 1102, to reduce the number/frequency of reading and writing for the first physical sub-memory of the memory circuit 1102, to reduce the power consumption of reading and writing for the memory circuit 1102.

By doing so, in the embodiment of the invention, the LDPC decoding result can be outputted instantly after it has been decoded and the calculation of next decoding schedule can be performed at the same time. In addition, this can also reduce the power consumption of a memory.

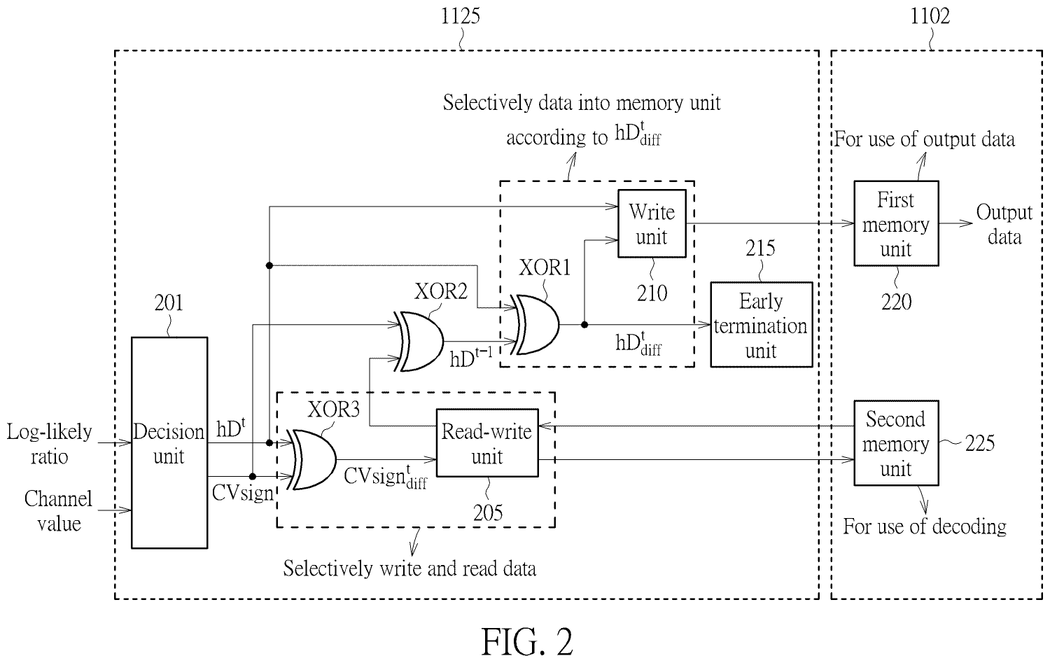

Refer to FIG. 2. FIG. 2 is a schematic diagram of circuits and operations of the syndrome calculation circuit 1125 and the memory circuit 1102 shown in FIG. 1 according to the embodiment of the invention. As shown in FIG. 2, the memory circuit 1102 includes a first memory unit 220 for storing output data and a second memory unit 225 for storing data for decoding. The first memory unit 220 is, for example, a first physical sub-memory, and the second memory unit 225 is, for example, a second physical sub-memory. The syndrome calculation circuit 1125 includes a decision unit 201, three exclusive-OR gates XOR1˜XOR3, a read-write unit 205, a write unit 210, and an early termination unit 215. The above units/circuits can all be implemented through hardware or firmware.

The decision unit 201 is used to receive the log-likely ratio generated from the variable node circuit 1105 and the outputted channel value, so as to generate a hard decision result hD^{t} of the (t)-th iterative decoding, and generates the reference value based on the channel value, e.g. outputting and providing a hard decision result/data CVsign before the iterative decoding is started. The hard decision result/data CVsign before the iterative decoding is started is for example an initial hard decision result before all the iterations of iterative decoding are started, e.g. the sign value of the channel value and has the value of all bits as ‘0’ (but not limited).

The exclusive-OR unit XOR3 is coupled to the decision unit 201 and is used to perform an exclusive-OR operation upon a hard decision result hD^{t} of the (t)-th iterative decoding and an initial hard decision result that are is not yet iteratively decoded (i.e. performing the exclusive-OR operation upon the hard decision data that are not yet decoded and has been decoded) so as to generate a difference value CVsign_{diff}^{t} generated after the (t)-th iterative decoding into the read-write unit 205. That is, the exclusive-OR unit XOR3 is used to perform an exclusive-OR operation upon the values of data of the hard decision results, that are not yet decoded and has been decoded, to calculate and determine whether the two values are different or not. If the two values are identical, then the difference value CVsign_{diff}^{t} indicates that for example the values of all bits are ‘0’. Otherwise, if the two values are different, then at least one bit of the difference value CVsign_{diff}^{t} is used to indicate ‘1’ to indicate that a data change occurs between the data of the hard decision results that are not yet decoded and has been decoded; that is, bit(s) of this codeword is/are flipped.

Accordingly, when receiving at least one bit of the difference value CVsign_{diff}^{t} indicates ‘1’, the read-write unit 205 writes and stores the difference value CVsign_{diff}^{t} into the second memory unit 225 for the use in decoding calculations. When the difference value CVsign_{diff}^{t} indicates that for example the values of all bits are ‘0’, the read-write unit 205 is used to not to control the second memory unit 225 to perform a write operation at a specific address. In other words, this can reduce the writings of the second memory unit 225 so as to save power. When the read-write unit 205 does not control the second memory unit 225 to perform the write operation at the specific address, the read-write unit 205 is arranged to simultaneously mark the specific address with an unwritten mark, so that the read-write unit 205 can determine whether to read the second memory unit 225 according to the content marked at the specific address when needing the difference value CVsign_{diff}^{t} later. For example, when a specific address corresponding to the difference value CVsign_{diff}^{t} is not marked with an unwritten mark, the read-write unit 205 controls the second memory unit 225 to read the content of the difference value CVsign_{diff}^{t} stored at the specific address. On the contrary, when the specific address is marked with an unwritten mark, the read-write unit 205 controls the second memory unit 225 to not to perform a reading operation to save power, and it directly outputs data of the default value having all bit values ‘0’ as a difference value CVsign_{diff}^{t}. In this way, the power consumption when reading and writing the second memory unit 225 can be reduced. In other words, when the difference value CVsign_{diff}^{t} indicates that a data change occurs, the read-write unit 205 writes and stores the difference value CVsign_{diff}^{t} to a specific address in the second memory unit 225 of the memory circuit 1102. When the difference value CVsign_{diff}^{t} indicates that no data changes occur, the read-write unit 205 does not perform a writing operation upon the second memory unit 225 of the memory circuit 1102 but mark an unwritten mark for the specific address. When it is needed to read data at the specific address and the specific address is not marked with the unwritten mark, the read-write unit 205 performs a read operation upon the second memory unit 225 of the memory circuit 1102 to read out the difference value stored at the specific address and output the difference value to the exclusive-OR unit XOR2. When it is needed to read data at the specific address and the specific address is marked with the unwritten mark, the read-write unit 205 does not perform the read operation upon the second memory unit 225 of the memory circuit 1102 and directly uses the default value as the difference value to output the difference value into the exclusive-OR unit XOR2.

The exclusive-OR unit XOR2 performs the exclusive-OR operation upon the initial hard decision result CVsign, that is not yet iteratively decoded, and the difference value CVsign_{diff}^{t-1} of the (t−1)-th iterative decoding to generate and output a hard decision result hD^{t<1} of the (t−1)-th iterative decoding into the exclusive-OR unit XOR1.

When the exclusive-OR unit XOR1 receives the hard decision result hD^{t-1} of the (t−1)-th iterative decoding, the exclusive-OR unit XOR1 simultaneously receives the hard decision result hD^{t} of the (t)-th iterative decoding from the decision unit 201, and then performs the exclusive-OR operation upon the hard decision result hD^{t-1} and hard decision result hD^{t} to generate a difference value hD_{diff}^{t} between the hard decision results of the (t−1)-th iterative decoding and (t)-th iterative decoding to output the difference value hD_{diff}^{t} to the early termination unit 215 and the write unit 210.

The early termination unit 215 can early determine whether a valid codeword has been found based on the difference value hD_{diff}^{t}. For example, during the procedure of each (t)-th iterative decoding, the difference value hD_{diff}^{t}, which can be used to indicate whether the hard decision result hD^{t} of the (t)-th iterative decoding is identical to the hard decision result hD^{t-1} of the (t−1)-th iterative decoding, can be transmitted to the early terminal termination unit 215, so the early termination unit 215 can accordingly know and obtain the result of a codeword, that is flipped or un-flipped, after each iterative decoding is finished, so as to calculate a syndrome value. At this time, if the calculated syndrome value is zero, then this indicates that a valid codeword is found, and the entire iterative decoding operation can be interrupted and the decoding operation is completed.

In addition, the write unit 210 can selectively determine whether to write, update, and store the hard decision result hD^{t} of the (t)-th iterative decoding into the first memory unit 220. For example, when the difference value hD_{diff}^{t} indicates that the hard decision result hD^{t} of the (t)-th iterative decoding is identical to the hard decision result hD^{t-1} of the (t−1)-th iterative decoding, i.e. no data changes occur between results of two consecutive hard decisions, in this situation there is no need to perform data writing and updating, and the write unit 210 can control the first memory unit not to perform writing operations to save power. On the contrary, when the difference value hD_{diff}^{t} indicates that the hard decision result hD^{t} of the (t)-th iterative decoding is different from the hard decision result hD^{t-1} of the (t−1)-th iterative decoding, i.e. a data change occurs between the results of two consecutive hard decisions, in this situation it is needed to perform data writing and updating, and the write unit 210 can write, update, and store the hard decision result hD^{t} of the (t)-th iterative decoding into the first memory unit 220.

Accordingly, equivalently the initial hard decision result CVsign is used as a reference value. In one embodiment, initially during the procedure of the first iterative decoding, the syndrome calculation circuit 1125 stores and writes the initial hard decision result CVsign into the first memory unit 220 without performing write operation upon the second memory unit 225. This is not intended to be a limitation of the invention.

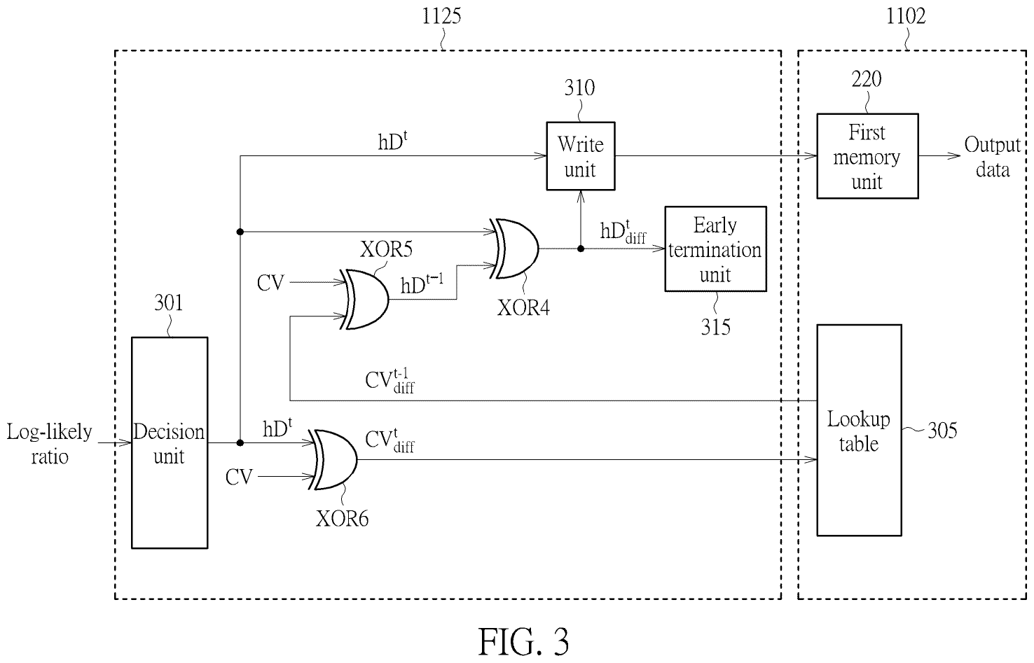

Furthermore, the reference value to be compared may also be a channel value. Refer to FIG. 3. FIG. 3 is a schematic diagram of circuits and operations of the syndrome calculation circuit 1125 and the memory circuit 1102 shown in FIG. 1 according to another embodiment of the invention. As shown in FIG. 3, the memory circuit 1102 includes the first memory unit 220 for storing output data and a lookup table 305 used for storing data for decoding calculations. The first memory unit 220 is, for example, a first physical sub-memory. The lookup table 305 may be implemented by using a second physical memory. The syndrome calculation circuit 1125 includes a decision unit 301, three exclusive-OR units XOR4˜XOR6, a write unit 310, and an early termination unit 315. The above units can be implemented through hardware or firmware.

The decision unit 301 is configured to receive the log-likely ratio generated from the variable node circuit 1105 and perform a hard decision operation based on the log-likely ratio to generate a hard decision result hD^{t} of the (t)-th iterative decoding. The exclusive-OR unit XOR6 is coupled to the decision unit 301 and is used to receive a hard decision result hD^{t} of the (t)-th iterative decoding and a channel value CV (i.e. the reference value), and is used to perform an exclusive-OR operation upon the hard decision result hD^{t} (of the (t)-th iterative decoding) and the channel value CV (which is used as a reference value in this situation) to generate a difference value CV_{diff}^{t} of the (t)-th iterative decoding and to write and store the difference value CV_{diff}^{t} in the lookup table 305 to update the content of a specific field in the lookup table 305; that is, the exclusive-OR unit XOR6 performs the exclusive-OR operation upon the pre-decoded data and post-decoded data. Specifically, for the (t)-th iterative decoding, the lookup table 305 may, for example, store multiple difference values, of the (t)-th iterative decoding, corresponding to multiple fragments of bits (or multiple portions) of a specific codeword. Each difference value can be used to indicate whether a data change occurs between a hard decision result hD^{t} of the (t)-th iteration corresponding to a corresponding fragment and a reference value.

The exclusive-OR unit XOR5 is coupled to the channel value CV. Before one or more difference values in the lookup table 305 are updated (e.g. before the difference value CV_{diff}^{t} of the (t)-th iterative decoding is written to update the difference value CV of the (t−1)-th iterative decoding and stored in the lookup table 305), the difference value CV_{diff}^{t-1} will be read out and outputted to the exclusive-OR unit XOR5. The exclusive-OR unit XOR5 is used to perform the exclusive-OR operation upon the difference value CV_{diff}^{t-1}, of the (t−1)-th iterative decoding, and the channel value CV to generate a hard decision result hD^{t-1} of the (t−1)-th iterative decoding into the exclusive-OR unit XOR4. The exclusive-OR unit XOR4 is used to receive the hard decision result hD^{t} of the (t)-th iterative decoding and hard decision result hD^{t-1} of the (t−1)-th iterative decoding and to perform the exclusive-OR operation upon the hard decision result hD^{t} and hard decision result hD^{t-1} to generate a difference value hD_{diff}^{t} between the hard decision results of the (t)-th iterative decoding and the (t−1)-th iterative decoding into the early termination unit 315 and the write unit 310.

Similarly, the early termination unit 315 can early determine whether a valid codeword is found based on the difference value hD_{diff}^{t}. For example, during operation of each (t)-th iterative decoding, the difference value hD_{diff}^{t}, which can be used to indicate whether a hard decision result hD^{t} of the (t)-th iterative decoding is identical to a hard decision result hD^{t-1} of the (t−1)-th iterative decoding, is transmitted to the early termination unit 315, and thus the early termination unit 315 accordingly can know and obtain the codeword result which is flipped or un-flipped during calculations of each iterative decoding, so as to calculate a syndrome value. In this situation, if the calculated syndrome value is zero, this indicates that a valid codeword is found, and the entire iterative decoding operation can be interrupted and the decoding operation is completed.

In addition, the write unit 310 can selectively determine whether to write, update, and store the hard decision result hD^{t} of the (t)-th iterative decoding into the first memory unit 220. For example, when the difference value hD_{diff}^{t} indicates that the hard decision result hD^{t} of the (t)-th iterative decoding is identical to the hard decision result hD^{t-1} of the (t−1)-th iterative decoding, i.e. no data changes occur between results of two consecutive hard decisions, in this situation there is no need to perform data writing and updating, and the write unit 310 can control the first memory unit 220 not to perform writing operations to save power. On the contrary, when the difference value hD_{diff}^{t} indicates that the hard decision result hD^{t} of the (t)-th iterative decoding is different from the hard decision result hD^{t-1} of the (t−1)-th iterative decoding, i.e. a data change occurs between the results of two consecutive hard decisions, in this situation it is needed to perform data writing and updating, and the write unit 310 can write, update, and store the hard decision result hD^{t} of the (t)-th iterative decoding into the first memory unit 220.

Thus, the channel value CV equivalently is used as a reference value. In one embodiment, initially the syndrome calculation circuit 1125 may store and write the channel value CV into the first memory unit 220, and does not need to perform the write operation upon the second memory unit 225. This is not intended to be a limitation of the invention.

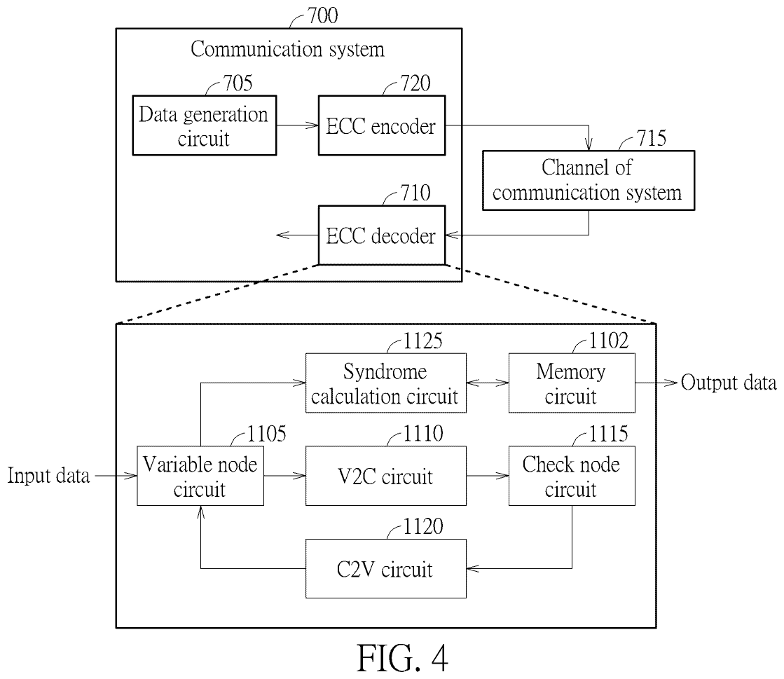

Similarly, the above-mentioned ECC decoder (or decoder circuit) can also be applied in a communication system. Refer to FIG. 4. FIG. 4 is a schematic diagram of a communication system circuit 700 according to an embodiment of the invention. As shown in FIG. 4, the communication system circuit 700 is for example a wireless transceiver and includes a data generation circuit 705, an ECC encoder 720, and an ECC decoder 710. The data generation circuit 705 is used to generate a specific data such as data of a codeword. The ECC encoder 720 performs ECC encoding (such as an LDPC encoding operation) upon the specific codeword to generate an encoded codeword, and transmits the encoded codeword to a communication system channel 715 such as a wireless transmission medium (but not limited to). Then the ECC decoder 710 is used to receive the encoded codeword and perform a decoding operation upon the encoded codeword to perform calculations of iterative decoding for multiple times to generate correct codeword data. The ECC decoder 710 is, for example, an LDPC decoder circuit and includes a memory circuit 1102, a variable node circuit 1105, a V2C circuit 1110, a check node circuit 1115, a C2V circuit 1120, and a syndrome calculation circuit 1125. The operations and functions are the same as those of the aforementioned circuit components with the same numbers and will not be repeated again.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A decoder circuit, comprising:
a variable node circuit, for receiving data of a specific codeword of an input data as a channel value to generate or update a variable-to-check message and generate a log-likely ratio to a syndrome calculation circuit;
a variable-to-check circuit, coupled to the variable node circuit, for converting the variable-to-check message from a variable node domain into a check node domain to generate a converted variable-to-check message;
a check node circuit, coupled to the variable-to-check circuit, for performing a minimization calculation based on the converted variable-to-check message to generate a check-to-variable message;
a check-to-variable circuit, coupled to the check node circuit, for converting the check-to-variable message from the check node domain into the variable node domain to generate a converted check-to-variable message, to make the variable node circuit perform a sum calculation to update the variable-to-check message and perform another sum calculation to update the log-likely ratio based on the converted check-to-variable message;
the syndrome calculation circuit, coupled to the variable node circuit, for performing a hard decision operation based on the log-likely ratio to determine whether to flip information of at least one bit in the specific codeword to generate an output codeword; and
a memory circuit, coupled to the syndrome calculation circuit, for storing the output codeword generated by the syndrome calculation circuit as an output data;
wherein the syndrome calculation circuit compares a reference value with a value of the hard decision result to generate a difference value and selectively stores and writes the hard decision result value into the memory circuit according to the difference value to reduce the number of reading and writing of the memory circuit.

2. The decoder circuit of claim 1, wherein the memory circuit comprises:
a first memory unit, coupled to the syndrome calculation circuit, for storing the output data; and
a second memory unit, coupled to the syndrome calculation circuit, for temporarily storing the difference value.

3. The decoder circuit of claim 2, wherein the first memory unit is a first physical sub-memory, the second memory unit is a second physical sub-memory, and the first physical sub-memory is different from the second physical sub-memory.

4. The decoder circuit of claim 2, wherein the syndrome calculation circuit comprises:
a decision unit, for performing the hard decision operation based on the log-likely ratio to generate a hard decision result of a (t)-th iterative decoding, and for generating the reference value based on the channel value;
a write unit, coupled to the first memory unit, the decision unit, and a first exclusive-OR unit;
a read-write unit, coupled to the second memory unit, a second exclusive-OR unit, and a third exclusive-OR unit;
an early termination unit, coupled to the first exclusive-OR unit;
the first exclusive-OR unit, coupled to the decision unit and the second exclusive-OR unit;
the second exclusive-OR unit, coupled to the read-write unit, the decision unit, and the first exclusive-OR unit;
the third exclusive-OR unit, coupled to the decision unit and the read-write unit;
wherein the third exclusive-OR unit is used to generate a first difference value based on the hard decision result of the (t)-th iterative decoding and the reference value; the read-write unit controls the second memory unit of the memory circuit to selectively write and store the first difference value, and selectively reads the second memory unit of the memory circuit to obtain and output a second difference value into the second exclusive-OR unit; the second exclusive-OR unit generates a hard decision result of a (t−1)-th iterative decoding based on the second difference value and the reference value; the first exclusive-OR unit generates a third difference value between the hard decision result of the (t−1)-th iterative decoding and the hard decision result of the (t)-th iterative decoding based on the hard decision result of the (t−1)-th iterative decoding and the hard decision result of the (t)-th iterative decoding; the early termination unit determines whether a valid codeword is found based on the third difference value; and, the write unit determines whether to write the hard decision result of the (t)-th iterative decoding into the first memory unit of the memory circuit according to the third difference value.

5. The decoder circuit of claim 4, wherein when the first difference value indicates that a data change occurs, the read-write unit writes and stores the first difference value into a specific address in the second memory unit of the memory circuit; when the first difference value indicates that no data changes occur, the read-write unit marks the specific address with an unwritten mark without performing a write operation upon the second memory unit of the memory circuit; when the specific address needs to be read and the specific address is not marked with the unwritten mark, the read-write unit performs a read operation upon the second memory unit of the memory circuit to read the first difference value stored at the specific address to output the first difference value into the second exclusive-OR unit; and, when the specific address needs to be read and the specific address is marked with the unwritten mark, the read-write unit directly uses a default value as the first difference value to output the first difference value into the second exclusive-OR unit without performing the read operation upon the second memory unit of the memory circuit.

6. The decoder circuit of claim 4, wherein when the third difference value indicates that a data change occurs, the write unit is used to write the hard decision result of the (t)-th iterative decoding into the first memory unit of the memory circuit; and, when the third difference value indicates that no data changes occur, the write unit is used to not control the first memory unit of the memory circuit to perform a write operation.

7. The decoder circuit of claim 4, wherein the reference value is a sign value of the channel value.

8. The decoder circuit of claim 2, wherein the second memory unit is used to store a content of a lookup table, and the syndrome calculation circuit comprises:
a decision unit, for performing the hard decision operation based on the log-likely ratio to generate a hard decision result of a (t)-th iterative decoding;
a write unit, coupled to the first memory unit, the decision unit, and a first exclusive-OR unit;
an early termination unit, coupled to the first exclusive-OR unit;
the first exclusive-OR unit, coupled to the decision unit and the second exclusive-OR unit;
the second exclusive-OR unit, coupled to the second memory unit of the memory circuit and the first exclusive-OR unit;
the third exclusive-OR unit, coupled to the decision unit and the second memory unit of the memory circuit;
wherein the third exclusive-OR unit is used to generate a first difference value based on the hard decision result of the (t)-th iterative decoding and the reference value and to write the first difference value into the second memory unit of the memory circuit to update a content of a field of the lookup table; the second exclusive-OR unit generates a hard decision result of a (t−1)-th iterative decoding based on a second difference value obtained from the lookup table and the reference value; the first exclusive-OR unit generates a third difference value between the hard decision result of the (t)-th iterative decoding and the hard decision result of the (t−1)-th iterative decoding based on the hard decision result of the (t)-th iterative decoding and the hard decision result of the (t−1)-th iterative decoding; the early termination unit determines whether a valid codeword is found based on the third difference value; and, the write unit determines whether to write the hard decision result of the (t)-th iterative decoding into the first memory unit of the memory circuit according to the third difference value.

9. The decoder circuit of claim 8, wherein when the third difference value indicates that a data change occurs, the write unit is used to write the hard decision result of the (t)-th iterative decoding into the first memory unit of the memory circuit; and, when the third difference value indicates that no data changes occur, the write unit is used to not control the first memory unit of the memory circuit to perform a write operation.

10. The decoder circuit of claim 8, wherein the reference value is the channel value.

11. A flash memory controller, comprising:
an encoder, for performing an encoding operation upon a write data sent from a host device to write the write data into a flash memory; and
a decoder circuit, for performing a decoding operation upon a read data read from the flash memory to generate a decoded data;
wherein the decoder circuit comprises:
a variable node circuit, for receiving the read data as data of a specific codeword of an input data and using the data of the specific codeword as a channel value to generate or update a variable-to-check message and generate a log-likely ratio to a syndrome calculation circuit;
a variable-to-check circuit, coupled to the variable node circuit, for converting the variable-to-check message from a variable node domain into a check node domain to generate a converted variable-to-check message;
a check node circuit, coupled to the variable-to-check circuit, for performing a minimization calculation based on the converted variable-to-check message to generate a check-to-variable message;
a check-to-variable circuit, coupled to the check node circuit, for converting the check-to-variable message from the check node domain into the variable node domain to generate a converted check-to-variable message, to make the variable node circuit perform a sum calculation to update the variable-to-check message and perform another sum calculation to update the log-likely ratio based on the converted check-to-variable message;
the syndrome calculation circuit, coupled to the variable node circuit, for performing a hard decision operation based on the log-likely ratio to determine whether to flip information of at least one bit in the specific codeword to generate an output codeword; and
a memory circuit, coupled to the syndrome calculation circuit, for storing the output codeword generated by the syndrome calculation circuit as an output data which is used as the decoded data;
wherein the syndrome calculation circuit compares a reference value with a value of the hard decision result to generate a difference value and selectively stores and writes the hard decision result value into the memory circuit according to the difference value to reduce the number of reading and writing of the memory circuit.

12. A decoding method of a decoder circuit, comprising:
using a variable node circuit to receive data of a specific codeword of an input data as a channel value to generate or update a variable-to-check message and generate a log-likely ratio to a syndrome calculation circuit;
converting the variable-to-check message from a variable node domain into a check node domain to generate a converted variable-to-check message;
using a check node circuit to perform a minimization calculation based on the converted variable-to-check message to generate a check-to-variable message;
converting the check-to-variable message from the check node domain into the variable node domain to generate a converted check-to-variable message, to make the variable node circuit perform a sum calculation to update the variable-to-check message and perform another sum calculation to update the log-likely ratio based on the converted check-to-variable message;
using the syndrome calculation circuit to perform a hard decision operation based on the log-likely ratio to determine whether to flip information of at least one bit in the specific codeword to generate an output codeword;
providing a memory circuit for storing the output codeword generated by the syndrome calculation circuit as an output data; and
using the syndrome calculation circuit to compare a reference value with a value of the hard decision result to generate a difference value and to selectively store and write the hard decision result value into the memory circuit according to the difference value to reduce the number of reading and writing of the memory circuit.

13. The decoding method of claim 12, further comprising:
using a first memory unit for storing the output data; and
using a second memory unit for temporarily storing the difference value.

14. The decoding method of claim 13, wherein the first memory unit is a first physical sub-memory, the second memory unit is a second physical sub-memory, and the first physical sub-memory is different from the second physical sub-memory.

15. The decoding method of claim 13, further comprising:
performing the hard decision operation based on the log-likely ratio to generate a hard decision result of a (t)-th iterative decoding and generating the reference value based on the channel value;
providing a first exclusive-OR unit;
providing a second exclusive-OR unit;
providing a third exclusive-OR unit;
using the third exclusive-OR unit to generate a first difference value based on the hard decision result of the (t)-th iterative decoding and the reference value;
controlling the second memory unit of the memory circuit to selectively write and store the first difference value;
selectively reading the second memory unit of the memory circuit to obtain and output a second difference value into the second exclusive-OR unit;
using the second exclusive-OR unit to generate a hard decision result of a (t−1)-th iterative decoding based on the second difference value and the reference value;
using the first exclusive-OR unit to generate a third difference value between the hard decision result of the (t−1)-th iterative decoding and the hard decision result of the (t)-th iterative decoding based on the hard decision result of the (t−1)-th iterative decoding and the hard decision result of the (t)-th iterative decoding;
determining whether a valid codeword is found based on the third difference value; and
determining whether to write the hard decision result of the (t)-th iterative decoding into the first memory unit of the memory circuit according to the third difference value.

16. The decoding method of claim 15, further comprising:
when the first difference value indicates that a data change occurs, writing and storing the first difference value into a specific address in the second memory unit of the memory circuit;
when the first difference value indicates that no data changes occur, marking the specific address with an unwritten mark without performing a write operation upon the second memory unit of the memory circuit;
when the specific address needs to be read and the specific address is not marked with the unwritten mark, performing a read operation upon the second memory unit of the memory circuit to read the first difference value stored at the specific address to output the first difference value into the second exclusive-OR unit; and
when the specific address needs to be read and the specific address is marked with the unwritten mark, directly using a default value as the first difference value to output the first difference value into the second exclusive-OR unit without performing the read operation upon the second memory unit of the memory circuit.

17. The decoding method of claim 15, further comprising:
when the third difference value indicates that a data change occurs, writing the hard decision result of the (t)-th iterative decoding into the first memory unit of the memory circuit; and
when the third difference value indicates that no data changes occur, not controlling the first memory unit of the memory circuit to perform a write operation.

18. The decoding method of claim 15, wherein the reference value is a sign value of the channel value.

19. The decoding method of claim 13, wherein the second memory unit is used to store a content of a lookup table, and the method further comprises:
performing the hard decision operation based on the log-likely ratio to generate a hard decision result generated by a (t)-th iterative decoding;
providing a first exclusive-OR unit;
providing a second exclusive-OR unit;
providing a third exclusive-OR unit;
using the third exclusive-OR unit to generate a first difference value based on the hard decision result of the (t)-th iterative decoding and the reference value and to write the first difference value into the second memory unit of the memory circuit to update a content of a field of the lookup table;
using the second exclusive-OR unit to generate a hard decision result generated by a (t−1)-th iterative decoding based on a second difference value obtained from the lookup table and the reference value;
using the first exclusive-OR unit to generate a third difference value between the hard decision result of the (t)-th iterative decoding and the hard decision result of the (t−1)-th iterative decoding based on the hard decision result of the (t)-th iterative decoding and the hard decision result of the (t−1)-th iterative decoding;
determining whether a valid codeword is found based on the third difference value; and
determining whether to write the hard decision result of the (t)-th iterative decoding into the first memory unit of the memory circuit according to the third difference value.

20. The decoding method of claim 19, further comprising:
when the third difference value indicates that a data change occurs, writing the hard decision result of the (t)-th iterative decoding into the first memory unit of the memory circuit; and
when the third difference value indicates that no data changes occur, not controlling the first memory unit of the memory circuit to perform a write operation.

21. The decoding method of claim 19, wherein the reference value is the channel value.
